(19) United States
(12) Patent Application Publication
(10) Pub. No.: US 2025/0304432 A1
(43) Pub. Date: Oct. 2, 2025

(54) Monolithic Microelectromechanical Systems Based Spatial Light Modulators with Two-dimensional Modulators

(71) Applicant: SILICON LIGHT MACHINES CORPORATION, San Jose, CA (US)

(72) Inventors: Alexander Payne, Ben Lommond, CA (US); James Hunter, Campbell, CA (US); Tianbo Liu, San Jose, CA (US); Lars Eng, Los Altos, CA (US); Stephen Hamann, Mountain View, CA (US)

(73) Assignee: SILICON LIGHT MACHINES CORPORATION, San Jose, CA (US)

(21) Appl. No.: 19/098,508

(22) Filed: Apr. 2, 2025

Related U.S. Application Data
(60) Provisional application No. 63/573,086, filed on Apr. 2, 2024.

(51) Int. Cl. B81B 7/00; B81C 1/00; G02B 26/08

(52) U.S. Cl. CPC B81B 7/0077; B81C 1/00246; G02B 26/0841; B81B 2201/042; B81B 2203/0172; B81B 2203/04; B81B 2207/015; B81B 2207/053; B81B 2207/07; B81C 2201/0105; B81C 2201/013

(57) ABSTRACT

Monolithic microelectromechanical systems (MEMS)-based spatial light modulators (SLM) are provided. Generally, the SLM includes a common electrode in or on a substrate, an electrostatically displaceable actuator including an actuator electrode suspended above an upper surface on the substrate, a first light reflective surface supported by and separated from the upper surface on the substrate by the actuator, and a driver monolithically integrated in the substrate below the SLM. The actuator includes a structural layer of tensile, amorphous silicon-germanium that also serves as an actuator electrode. The driver includes multiple layers of vias, metal interconnects, and complementary metal-oxide-semiconductor (CMOS) devices to electrically couple to the common electrode and actuator, and is operable to displace the actuator and first light reflective surface in response to voltages applied thereto.

### CROSS-REFERENCE TO RELATED APPLICATIONS

This application claims the benefit of priority under 35 U.S.C. 119(e) to U.S. Provisional Patent Application Ser. No. 63/573,086 filed Apr. 2, 2024, which is incorporated by reference herein in its entirety.

### TECHNICAL FIELD

This disclosure relates generally relates to spatial light modulators (SLMs), and more particularly to an integrated or monolithic microelectromechanical systems (MEMS) based two-dimensional (2D) SLMs including a driver integrally fabricated on a common substrate.

### BACKGROUND

Spatial light modulators (SLMs) include an array of one or more modulators that can control or modulate an incident beam of light in a spatial pattern that corresponds to an electrical input to the modulators. In one type of SLM an incident light beam, typically generated by a coherent light source, is reflected from the SLM modulated in intensity, phase, polarization and direction or angle. SLMs are increasingly being developed for use in various applications, including display systems, optical information processing and data storage, printing, maskless lithography, 3D printing, additive manufacturing, surface modification and optical phase modulation.

One type of reflective SLM potentially useful in the aforementioned applications is a microelectromechanical systems (MEMS) based SLM. MEMS-based SLMs typically include a multi-pixel array, in which each pixel includes one or more individual modulators each with an electrostatically deflectable element suspended over a substrate and having a light reflective surface or on a mirror coupled to the element. In operation light from a coherent light source is projected onto the array, and alignment of the light reflective surfaces is altered by a drive voltage applied between a common electrode in the substrate and individual electrodes in the deflectable element, causing electrostatic forces to displace some of the light reflective surfaces to modulate the phase, intensity or angle of reflected light from the array. Generally, the electrodes in the deflectable members are electrically grouped together to form a number of drive channels, each including one or more pixels.

The drive voltage is generated in a drive-circuitry or driver implemented as integrated circuit (IC) using (CMOS) technology. Because many of the materials and process parameters used to fabricate the drive-circuit are incompatible with those needed to fabricate MEMS modulators, MEMS-based SLMs often include a separate die or substrate on which the driver is fabricated wire bonded to a MEMS die on which the array of MEMS modulators (MEMS array) are fabricated, and packaged in a multi-chip module. However, this leads to slower switching speeds, lower drive channel counts, higher power consumption and decreased yields due wire bond failure.

Some success has been realized by fabricating the driver on a common substrate laterally separated from the MEMS array. Generally, this involves either fabricating the driver first or modifying the CMOS process flow and architecture to fabricate the MEMS array at least partially concurrently with drive-circuit. However, this typically negatively impacts the functioning of the drive-circuit, the MEMS modulators or both. In particular, it is noted that the high temperature deposition processes used to fabricate the MEMS modulators deleteriously modifies diffusions and silicides in CMOS transistors, and damages metal layers and vias. Additionally, metal and dielectric layers of the driver can be further damaged by etching and polishing steps used to fabricate the MEMS modulators. Finally, the top light reflective surfaces, which are polished by CMP, of the MEMs modulators, have a lower height above the surface of the substrate than the driver, limiting the number of CMOS layers that can be used, restricting driver functionality and hindering layout.

Accordingly, there is a need for a monolithic MEMS-based SLMs including a driver integrated in a common substrate with the modulators of the SLM. It is further desirable the integration not restrict layout or interfere with functioning of the driver.

### SUMMARY

Monolithic microelectromechanical systems (MEMS)-based spatial light modulators (SLM) are provided

Generally, the MEMS-based SLM includes a common electrode in or on a substrate, a number of electrostatically displaceable actuators suspended above an upper surface on the substrate, a first light reflective surface supported by and separated from the upper surface by the actuator, and a driver monolithically integrated in the substrate and interlevel dielectric levels below the SLM. Each actuator includes a structural layer of tensile, amorphous silicon-germanium that also serves as an actuator electrode. The driver electrically includes multiple layers of vias, metal layers, and complementary metal-oxide-semiconductor (CMOS) transistors or devices electrically coupled to the common electrode and the number of actuators, and is operable to displace each actuator in response to voltages applied thereto to independently modulate an amplitude, phase or both of light incident on the SLM.

In some embodiments, the actuator includes a central plate and a number of flexures extending from the central plate to a number of posts extending from the upper surface of the substrate and supporting the actuator above the upper surface, and the first light reflective surface is on a mirror supported by and separated from the actuator by a central post extending from the central plate. In one of these embodiments, the SLM further including a static faceplate disposed above the upper surface of the substrate, the static faceplate including a second light reflective surface facing away from the upper surface and adjacent to the first light reflective surface. The area of reflectivity of the first light reflective surface and second light reflective surface are substantially equal, so that the SLM is operable to modulate amplitude of light incident thereon by displacing the first light reflective surface so that light reflected from the first light reflective surface interferes with light reflected from the second light reflective surface.

In other embodiments, the SLM is a phase modulator and includes multiple adjacent modulators, each including an actuator supporting a light reflective surface, and arranged or grouped to form a number of pixels. The SLM is operable to individually control the actuators of modulators in each pixel, and between adjacent pixels, to modulate the phase, amplitude or both of light reflected from the light reflective surfaces of each pixel.

Further features and advantages of embodiments of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to a person skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts. Further, the accompanying drawings, which are incorporated herein and form part of the specification, illustrate embodiments of the present invention, and, together with the description, further serve to explain the principles of the invention and to enable a person skilled in the relevant art(s) to make and use the invention.

FIG. 1 is a schematic block diagram illustrating a cross-sectional view of a monolithic microelectromechanical systems (MEMS)-based spatial light modulator (SLM) including a driver integrally fabricated in a substrate and a two-dimensional (2D) modulator fabricated on top thereof;

FIG. 2 schematically illustrates forces on an actuator layer or actuator for a single 2D phase shift modulator and a resulting deformation;

FIGS. 3A to 3E are simplified schematic block diagrams illustrating a 2D modulator for use in a monolithic MEMS-based SLM, in which a first reflective surface is formed on a mirror supported by a central post above the actuator and including a second light reflective surface on a static faceplate disposed about the mirror;

FIGS. 4A to 4C are simplified schematic diagrams illustrating yet another embodiment of a 2D modulator including a single light reflective surface;

FIG. 5 is a planar top view and a side view of a generic Complex Spatial Light Modulator (CSLM) including 2D modulators of FIGS. 4A to 4C;

FIGS. 6A and 6B schematically illustrate operation of a pixel including multiple 2D modulators in a monolithic MEMS-based complex SLM for use in a phase-modulated system;

FIG. 7 is a planar top view illustrating an embodiment of a monolithic MEMS-based SLM including a multi-pixel, linear array of dense-packed, MEM-based 2D modulators;

FIG. 8 is an optics diagram illustrating light paths for an imaging system along a vertical or longitudinal axis of a monolithic MEMS-based SLM;

FIG. 9 is a flowchart of a method for fabricating a 2D modulator such as shown in FIGS. 4A to 4C; and

FIG. 10 is an intermediate MEMS structure of the 2D modulator formed by the method of FIG. 9.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION

Embodiments of an integrated or monolithic microelectromechanical systems (MEMS)-based spatial light modulators (SLM) including MEMS-based two-dimensional (2D) modulators or phase shift elements formed on a surface of a substrate overlying a driver integrally formed in the substrate below the modulators are provided.

In the following description, numerous specific details are set forth, such as specific materials, dimensions and processes parameters etc. to provide a thorough understanding of the present invention. However, particular embodiments may be practiced without one or more of these specific details, or in combination with other known methods, materials, and apparatuses. In other instances, well-known semiconductor design and fabrication techniques have not been described in particular detail to avoid unnecessarily obscuring the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

The terms “over,” “under,” “between,” and “on” as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. In contrast, a first layer “on” a second layer is in contact with that second layer. Additionally, the relative position of one layer with respect to other layers is provided assuming operations deposit, modify and remove films relative to a starting substrate without consideration of the absolute orientation of the substrate.

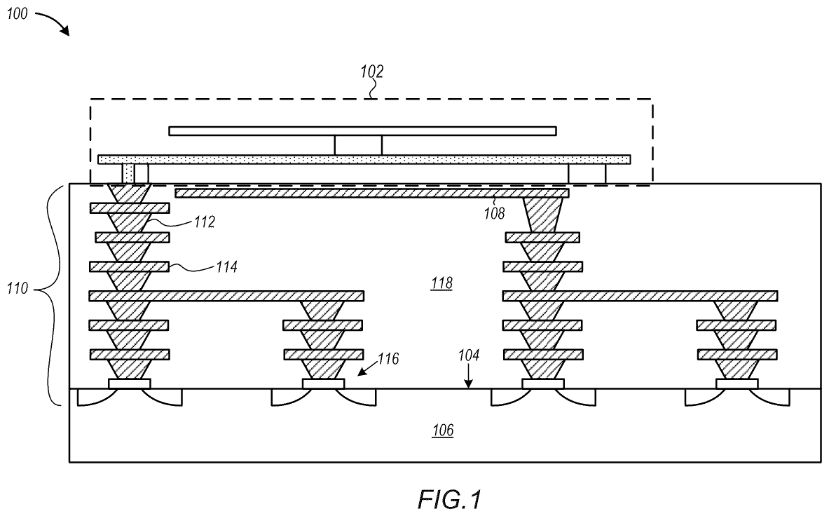

FIG. 1 is a schematic block diagram illustrating a cross-sectional view of a monolithic MEMS-based SLM including a number of two-dimensional (2D) MEMS-based light modulators or phase shift elements (hereinafter 2D modulators), and a driver integrally fabricated in a substrate underlying the 2D modulators. Briefly, referring to FIG. 1 the monolithic MEMS-based SLM 100 includes a number of 2D modulators 102, only one of which is shown, formed on or overlying a surface 104 of a substrate 106, a common electrode 108 formed in or on the surface of the substrate, and a driver 110 integrally formed in and on the substrate below the 2D modulators. The driver 110 generally includes multiple layers of vias 112, metal layers 114, and devices or transistors 116 fabricated in the substrate 106 and in a number of dielectric layers 118 overlying the surface of the substrate using a complementary metal-oxide-semiconductor (CMOS) technology. Generally, the driver 110 includes as many as six to eight metal layers, and lies partially or completely under one or more of the 2D modulators 102 and the common electrode 108, and the 2D modulators 102 each include an electrostatically displaceable actuator (not shown in this figure) suspended above an upper surface of the substrate. The driver 110 is coupled to the common electrode 108 and to movable actuators in the 2D modulators 102 through a number vias 112 and/or metal layers 114.

It is noted that although, only a single 2D modulator 102 is shown in FIG. 1, it will be understood that as explained in greater detail below the monolithic MEMS-based SLM 100 can and generally does include an array of from several hundred to several thousand 2D modulators overlying a shared common electrode 108, with a number of 2D modulators electrically coupled to a single drive channel to function as a single pixel.

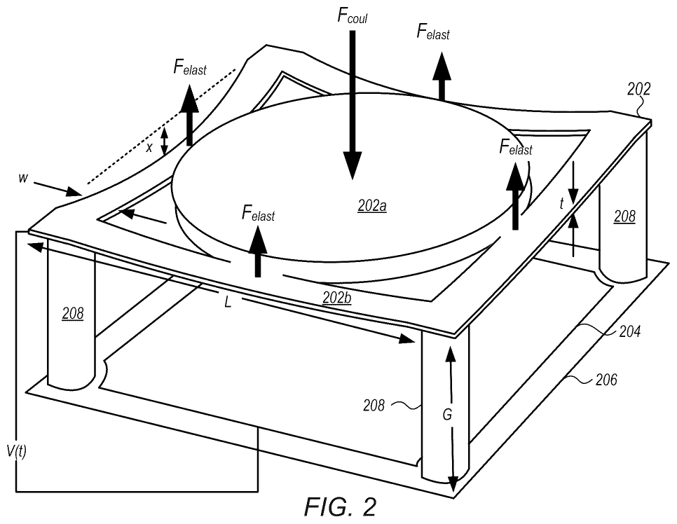

FIG. 2 schematically illustrates an actuator layer or actuator for a single 2D modulator and shows forces thereon resulting in deformation or movement. Referring to FIG. 2 the actuator 202 generally includes an electrostatically deflectable patterned central plate (CP 202a) and a number of flexures 202b through which the CP is suspended over a common electrode 204 in a substrate 206 by a number of posts 208 at corners thereof. Generally, the actuator 202 includes a taut, structural layer of tensile, amorphous silicon-germanium (SiGe layer) that also functions as an actuator electrode. By tensile, amorphous SiGe layer it is meant a layer of silicon-germanium with a molecular formula of the form Si₁₋ₓGeₓ that has been formed or processed to yield a layer substantially free of any crystalline structure, and having a modulus of elasticity from about 100 to about 120 GigaPascals (GPa), and more preferably about 110 GPa.

The SiGe layer can be a low temperature SiGe layer deposited using chemical vapor deposition (CVD), plasma enhanced CVD (PECVD) at a temperature of less than about 500 C to enable the 2D modulators to be formed over the substrate following fabrication of the driver without restricting layout of the driver or deleteriously impacting functioning CMOS transistors and devices of the driver. Preferably, the SiGe layer is further processed after deposition under conditions to yield a taut structural layer of tensile, amorphous SiGe. The processing can include implanting the SiGe layer with impurities at a concentration selected to change stress in the SiGe layer from a compressive stress to a tensile stress, followed by a low temperature (less than about 500 C) annealing of the implanted SiGe layer. More preferably, the SiGe layer is implanted with a dopant, which serves not only to change the stress in the SiGe layer to tensile but also to form a conductive implanted SiGe layer that also functions as the actuator electrode. Suitable impurities and dopants include Boron (B), Aluminum (Al), Gallium (Ga), Indium (In), Silicon (Si), Gold (Au) Xenon (Xe) Nitrogen (N), and Argon (Ar), ion implanted to a concentration of about from about of about 1E13 atoms/cm³ to about of about 1E18 atoms/cm³.

Referring to FIG. 2, a voltage potential (V(t)) applied between the actuator 202 and the common electrode 204 creates an electrostatic Coulomb attraction (F_{coul} in FIG. 2) that deflects the actuator a distance x towards the common electrode. The electrostatic force is balanced by an elastic restoring force (Fₑₗₐₛₜ in FIG. 2). The elastic restoring force, which is due to taut, tensile SiGe layer in the actuator 202, allows the actuator to revert back to a neutral state or position once the electrostatic force is removed.

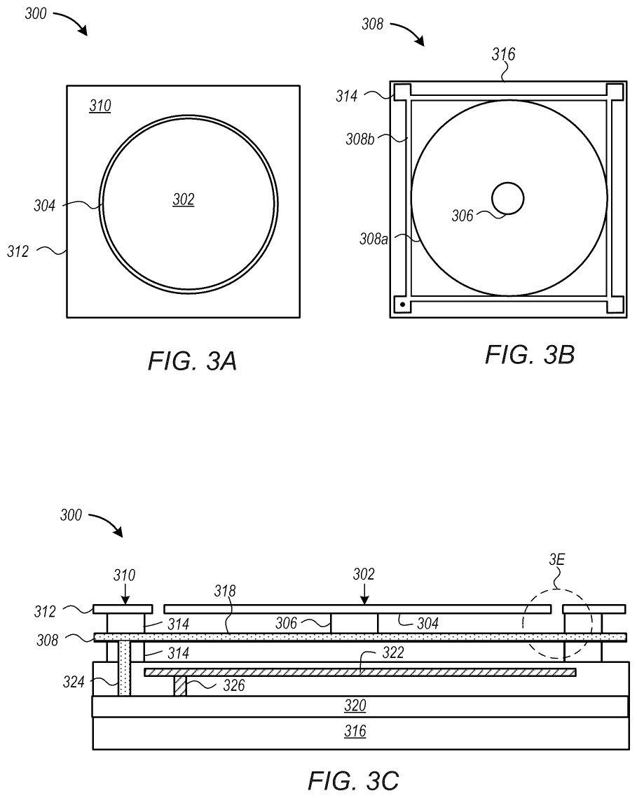

In one embodiment, shown in FIGS. 3A to 3E, a 2D diffractor or modulator 300 particularly suitable for use in a monolithic MEMS-based SLM for modulating an amplitude or magnitude of light incident thereon. Referring to FIGS. 3A to 3C, the 2D includes a first reflective surface 302 formed on a mirror 304 supported by a central post 306 above an electrostatically displaceable actuator 308, and a second light reflective surface 310 on a static faceplate 312 disposed about or surrounding the mirror. One example of such a 2D modulator is known as a Planar Light Valve (PLV™), and is commercially-available from Silicon Light Machines, Inc., of San Jose, California.

FIG. 3A is a top view of the 2D modulator 300. Referring to FIG. 3A, it is noted that the first light reflective surface 302 and the second light reflective surface 310 are sized and shaped to define reflective areas with substantially equal reflectivity, so that in operation deflection of the first light reflective surface brings light reflected therefrom into constructive or destructive interference with light reflected from the second light reflective surface to provide maximum contrast. When the 2D modulator 300 is in a quiescent or undriven state and the first light reflective surface 302 and the second light reflective surface 310 are co-planar, the 2D modulator is fully reflective. When the first light reflective surface 302 is displaced from the second light reflective surface 310 by a distance equal to n*λ/4, where n is an odd integer and λ is the wavelength of the incident light, the 2D modulator is in a fully diffracting or dark state. Generally, the driver and 1D modulator are operable to electrostatically displace the actuators in an analog range of distances so that a gray scale is achieved in the magnitude of the light reflected by the SLM,

FIG. 3B is a top view of the 2D modulator 300 in cut-away, with the faceplate 312 and mirror 304 removed, to reveal the central post 306 and actuator 308. Referring to FIG. 3B, the actuator 308 includes an electrostatically deflectable patterned central plate (CP 308a) and a number of flexures 308b through which the CP is flexibly or movably coupled to posts 314 suspending the actuator over a substrate 316.

FIG. 3C illustrates a schematic block diagram of a sectional side view of the 2D modulator 300 in a quiescent or un-driven state. Referring to FIG. 3C, the faceplate 312 overlying the actuator 308 and separated therefrom extensions of posts 314. As in the embodiment described above, the actuator 308 includes a taut, structural layer of tensile, amorphous SiGe (SiGe layer 318), which also functions as an actuator electrode.

The monolithic MEMS-based SLM further includes a driver 320 integrally formed in and/or on the substrate 316 at least partially underlying the 2D modulator 300 and a common electrode 322 formed in the substrate or in a dielectric layer on the substrate. The driver 320 is operable to generate a voltage between the common electrode 322 and the SiGe layer 318 in the actuator 308 to cause displacement of the CP 308a. The SiGe layer 318 is electrically coupled to one of a number drive channels in the driver 320 through a conductor 324 extending through one or more of the posts 314, and to the common electrode 322 through one or more vias 326 and metal layers (not shown in these figures).

FIG. 3D is a simplified schematic diagram illustrating a sectional side view of the 2D Modulator 300 of FIG. 3C in an active or driven state. The 2D Modulator 300 is operable so that electrostatic deflection of the CP 308a causes light reflected from the first light reflective surface 302 is brought into phase interference with light reflected from the second light reflective surface 310.

FIG. 3E is detailed view of a portion of the faceplate 312, the actuator 308, and the mirror 304 of the 2D modulator 300 shown in FIGS. 3C and 3D. Referring to FIG. 3E, as in the embodiment described above, the SiGe layer 318 can be deposited using CVD, or PECVD, preferably at a temperature of less than about 500 C to yield an amorphous SiGe layer. More preferably, the SiGe layer 318 is implanted, and annealed under conditions described above to yield a taut structural layer of tensile, amorphous SiGe.

The faceplate 312 and the mirror 304 also include a structural layer of SiGe layer 330 deposited at a temperature of less than about 500 C, to enable the 2D modulators 300 to be fabricated over the substrate 316 following fabrication of the driver 320 without restricting layout of the driver or deleteriously impacting functioning of CMOS transistors and devices of the driver.

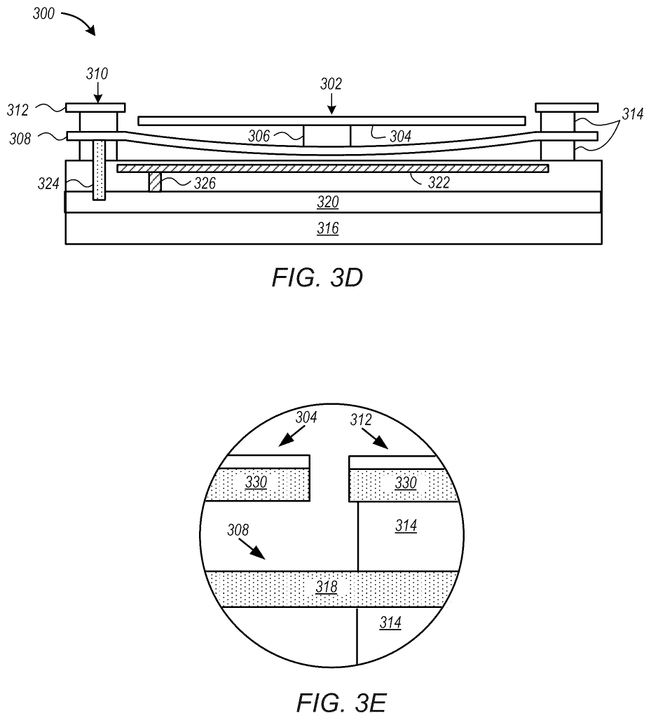

FIGS. 4A to 4C illustrate another embodiment of a 2D modulator suitable for use in a monolithic MEMS-based complex SLM. Referring to FIG. 4A to 4C, the 2D modulator includes a single light reflective surface on a mirror extending over substantially the entire modulator. It is noted that such a 2D modulator does not require a second light reflective surface. Instead each light reflective surface in each 2D modulator is moved or displaced in relation to the light reflective surface of an adjoining 2D modulator to modulate the amplitude, phase or both of light incident on a multi-pixel array of a monolithic MEMS-based SLM One example of such a 2D modulator is known as a complex 2D modulator, and is commercially-available from Silicon Light Machines, Inc., of San Jose, California.

FIG. 4A illustrates a schematic block diagram of a sectional side view of the 2D modulator 400 in a quiescent or un-driven state. Referring to FIG. 4A, the 2D modulator 400 includes an actuator 402 suspended over a surface on a substrate 404 by posts 406 at corners of the 2D modulator. As with the embodiment shown in FIGS. 3A and 3B, the actuator 402 includes an electrostatically deflectable central plate (CP 402a) and a number of flexures 402b through which the CP is flexibly or movably coupled to the posts 406. A light reflective surface 408 on a layer of reflective material 409 is formed or deposited on a mirror 410 supported above and separated from the CP 402a by a central post 412.

As in the embodiment described above, the actuator 402 includes a taut structural layer of tensile, amorphous SiGe (SiGe layer 414), which also functions as an actuator electrode.

The 2D modulator 400 further includes a driver 416 integrally formed in or on the substrate 404 underlying at least some of the 2D modulators 400, the driver operable to generate a voltage between a common electrode 418 and the SiGe layer 414 in the actuator 402 to cause displacement of the CP 402a. The SiGe layer 414 is electrically coupled to one of a number drive channels in the driver 416 through a conductor 420 extending through one or more of the posts 406, and to the common electrode 418 through one or more vias 422 and metal layers (not shown in these figures). Generally, multiple individual 2D modulators 400 are grouped or ganged together under control of a single drive channel to function as a single pixel in a multi-pixel, linear array of a monolithic MEMS-based SLM.

FIG. 4B is a simplified schematic diagram illustrating a sectional side view of the 2D Modulator 400 of FIG. 4B in an active or driven state. The 2D Modulator 400 is operable so that electrostatic deflection of the CP 402a causes light reflected from the light reflective surface 408 is brought into phase interference with light reflected from the light reflective surface of an adjacent 2D modulator.

FIG. 4C is detailed view of a portion of the actuator 402, and the mirror 410 of the 2D modulator 400 shown in FIGS. 4B and 4C. Referring to FIG. 4C as in the embodiments described above, the SiGe layer 414 can be deposited using CVD or PECVD, deposited at a low temperature of less than about 500 C. More preferably, the SiGe layer 414 is implanted and annealed under conditions described above to yield a taut structural layer of tensile, amorphous SiGe layer 414.

The mirror 410 also includes a structural layer of SiGe layer 426, deposited at a temperature of less than about 500 C, to enable the 2D modulators 400 to be fabricated over the substrate 404 following fabrication of the driver 416 without restricting layout of the driver or deleteriously impacting functioning CMOS transistors and devices of the driver.

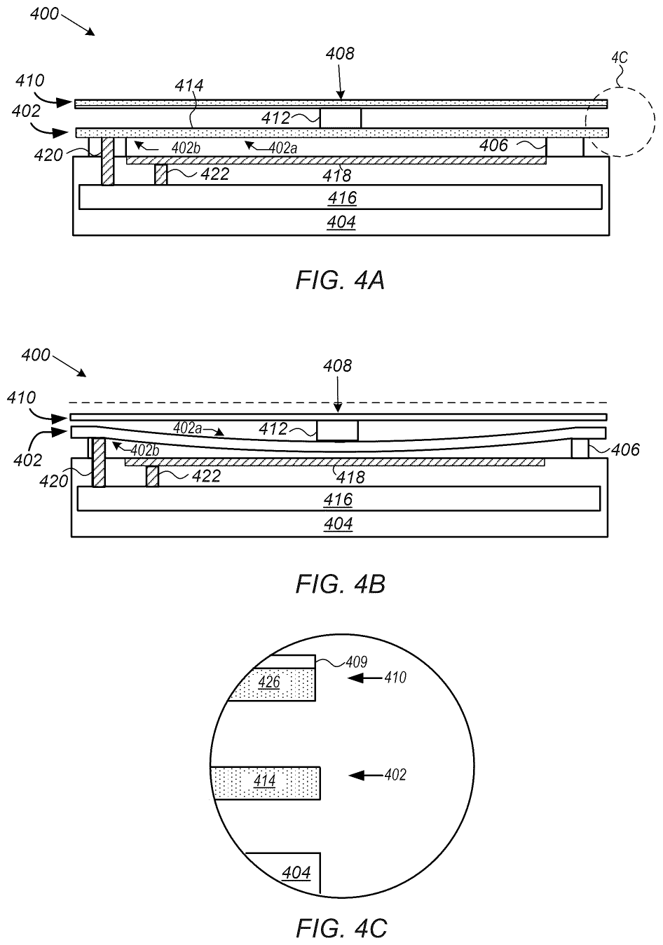

FIG. 5 includes a planar top view and a side view of a generic Complex Spatial Light Modulator (CSLM 500) including an embodiment of the 2D modulator shown in FIGS. 4A to 4C, and capable of simultaneously and independently modulating both amplitude and phase of light incident thereon. In general, a Complex SLM includes an array of a number of pixels, each pixel with multiple phase shift elements. The Complex SLM may also be preferably equipped with imaging optics including a Fourier filter adapted to resolve each pixel, but not the individual phase shift elements and other sub-pixel features. In the embodiment shown in FIG. 5, each of the 2D phase shift elements or modulators 502 include an electrostatically movable mirror 504 supported above and oriented to reflect light away from a negligible area or substantially nonreflective background 506. In one example, the movable mirror 504 comprises a piston mirror, and the background 506 may comprise a substantially nonreflective surface of a substrate 510. An arbitrary shape of the mirror 504 is shown in FIG. 5, as the mirror 504 may be implemented in various shapes (square, circular, etc.). Preferably, each pixel 508 consists of an m×n unit cell, where m≥2 and/or n≥2. In the example illustrated in FIG. 5, the pixel 508 comprises a 2×2 unit cell. Applicants have determined that a Complex SLM having an array of piston mirrors, such as shown in FIG. 5, can simultaneously and continuously modulate both the magnitude and phase of the light field.

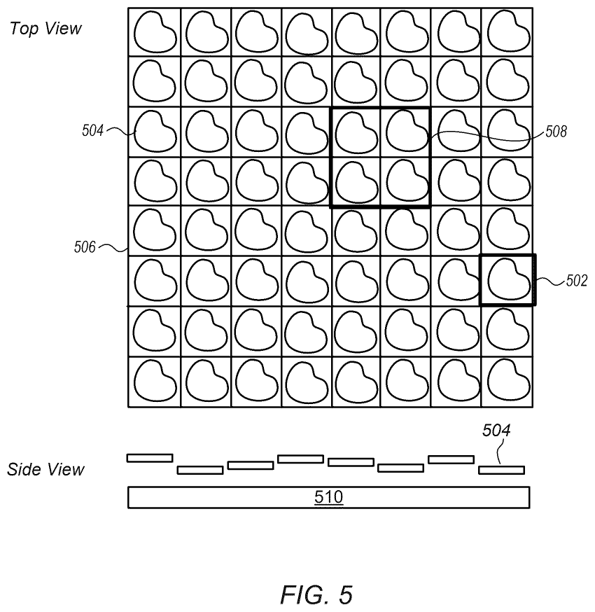

FIGS. 6A and 6B schematically illustrate operation of another embodiment of the 2D modulator shown in FIGS. 4A to 4C that is particularly useful for use in a phase-modulated system in which the monolithic MEMS-based SLM 600 operates as a phase modulator. Referring to FIG. 6A each pixel 602 includes multiple 2D modulators 604. The modulators 604 each include an electrostatically displaceable mirror or reflective surface 606. Preferably, the peripheral edges of the mirrors or reflective surface 606 supported by each of the actuators (not shown in these figures) abuts peripheral edges of mirrors supported by adjoining actuators, such that substantially none of the light incident on a monolithic MEMS-based SLM 600 passes between the mirrors to impinge on the actuators, flexures, posts or the upper surface.

In some embodiments, such as that shown, the modulators 604 along diagonal lines 608, 610, are electrically coupled to deflect in unison, by electrically interconnecting drive channels (not shown) below each 2D modulator 604 and applying a common drive voltage to an underlying common electrode. In this way, each pixel 602 receives two independent driving voltages to deflect diagonally opposed 2D modulators 604 as a group, denoted as group 1 and group 2 in FIG. 6A.

FIG. 6B schematically illustrate operation of multiple phase shift modulators in a monolithic MEMS-based SLM 600 particularly useful for use with a phase-modulated system. Referring to FIG. 6A each pixel 602 includes multiple 2D modulators 604. The modulators 604 each include an electrostatically displaceable mirror or reflective surface 606. Preferably, the modulators 604 along diagonal lines 608, 608, are electrically coupled to deflect in unison, by electrically interconnecting drive channels (not shown) below each 2D modulator and applying a common drive voltage to an underlying common electrode. In this way, each pixel 602 receives two independent driving voltages to deflect diagonally opposed 2D modulators 604 as a group, denoted as group 1 and group 2 in FIG. 6A. The two groups, of each pixel 602 can be controlled independently of the other pixels to allow coherent light reflected from one pixel to constructively or destructively interfere with light reflected from one or more adjacent pixels, thereby modulating the light incident thereon. More preferably, the 2D modulators 604 are deflectable through one or more wavelengths of light to enable both the phase and the amplitude of the reflected light to be modulated independently. FIG. 6B illustrates perspective views of a pixel 602 of the SLM 600 of FIG. 6A in (a) a quiescent state or mode, (b) a phase-modulated mode and (c) an amplitude and phase modulated mode, where δ is equal to a quarter wavelength of the light incident on the SLM.

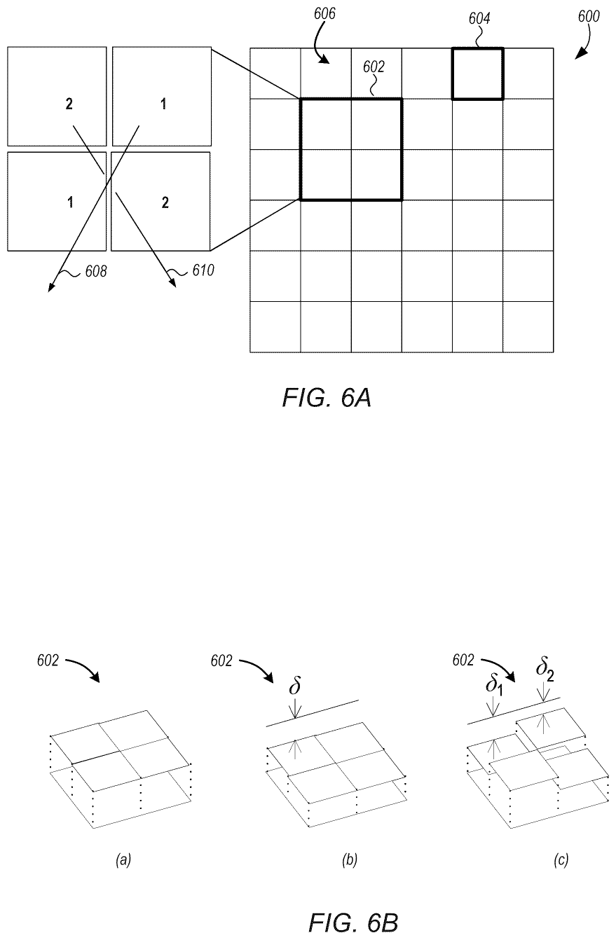

An exemplary embodiment of a monolithic MEMS-based SLM including a multi-pixel, linear array of dense-packed, MEM-based 2D modulators will now be described with reference to the diagrams of FIG. 7.

Referring to FIG. 7, in one embodiment the 2D modulators 702 can include a single light reflective surface, such as those shown in FIGS. 4A-4C, operable to continuously and independently modulate both the phase and magnitude of light incident thereon to form or function as a phased array. Generally, the 2D modulators 702 are arranged along a first, vertical or transverse axis 704 and a second horizontal or longitudinal axis 706 to form a rectangular linear array 708. Each of the 2D modulators 702 can function as a single pixel, or multiple 2D modulators can be grouped or coupled together to share a common drive channel or driver 710 to form a multi-modulator pixel 712. It will be understood that although the pixel 712 shown encompasses a full column of 2D modulators extending along the transverse axis 704 of the array 708, each channel or pixel can alternatively include any number of 2D modulators arranged extending over one or more columns or rows of the array. For example, in one embodiment of a monolithic MEMS-based SLM 700 particularly useful in imaging or optical manufacturing applications, each 2D modulator 702 forms a single pixel, and the array 708 includes thirty-two (32) 2D modulators or pixels grouped along the transverse axis 704, and two-hundred and fifty-six (256) 2D modulators along the longitudinal axis 706, forming a monolithic MEMS-based SLM 700 having 8192-channel/pixel. This configuration is particularly useful in applications, requiring intensity or amplitude modulation of light from a high power light source.

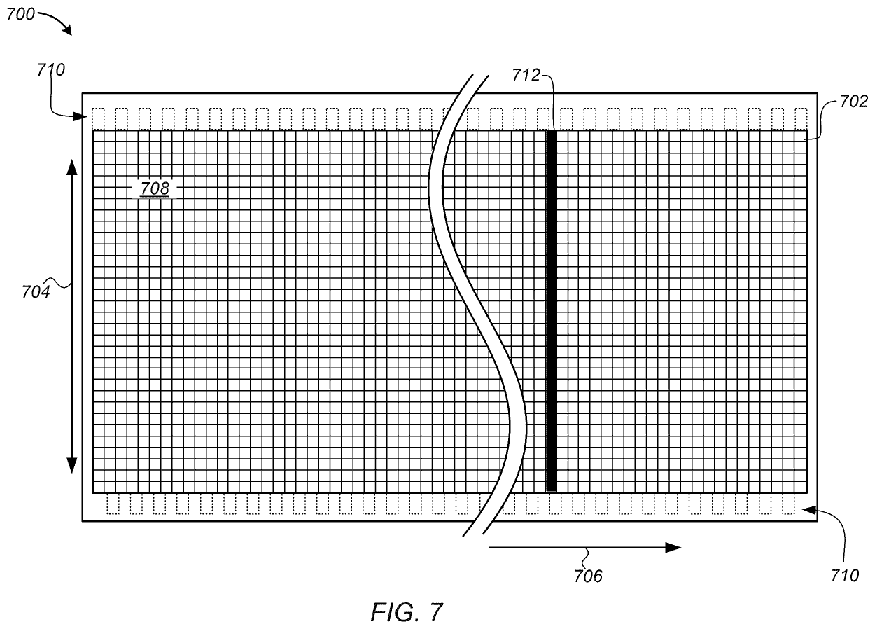

FIG. 8 is an optics diagram illustrating light paths for an imaging system 800 along a vertical or longitudinal axis of a monolithic MEMS-based SLM 802. FIG. 8 depicts a Fourier transform (F) filter configuration in accordance with an embodiment of the invention. The FT filter configuration may be used to control the imaging system to resolve light reflected from each pixel but not light reflected from each 2D modulator in each pixel in a spatial light modulator (SLM) 802, The configuration may include the SLM 802 in an object plane 804, a Fourier transform (FT) lens 806, a Fourier transform (FT) filter 808 in a Fourier transform (FT plane, an inverse Fourier transform (IFT) lens 810, and an image plane 812.

The FT lens 806 maps light from the SLM 802 to its transform, and the IFT lens 810 maps the light from the transform to an image (which is a filtered image of the light from the SLM 802, but upside-down) in the image plane 812. The spatial frequency spectrum of the light from the SLM 802 is formed at the FT plane 809.

FT or spatial filtering may be done by placing an amplitude and/or phase filter 808 at the FT plane 809. In one embodiment, the FT filter 808 may comprise an aperture with suitable apodization that transmits the 0^{th}-order of light and blocks the ±1 and all higher orders of light.

To create a bright pixel on the image, the corresponding SLM pixel is set in the mirror state. The incoming illumination will be passed undiffracted, i.e. as the 0^{th} order, through the central aperture of the FT filter 808 and transmitted maximally to the image plane 812. To create a dark pixel on the image, the corresponding SLM pixel is set in the maximally diffracting state. The incoming illumination will be diffracted maximally as ±1 and higher orders, which are blocked by the non-transmitting portion of the FT filter 808, Intermediate diffraction can be used to create gray levels.

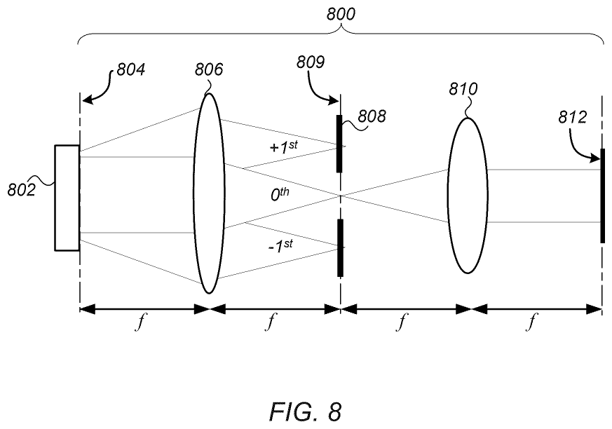

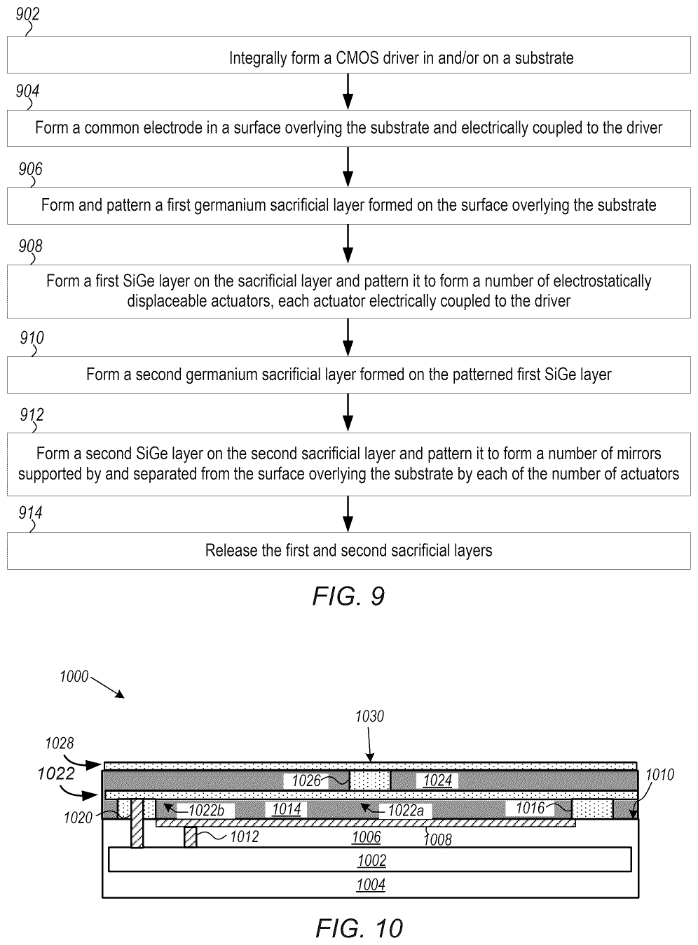

A method of fabricating a 2D modulator will now be described with reference to the flow chart of FIG. 9 and the intermediate MEMS structure 1000 of FIG. 10. Referring to FIGS. 9 and 10, the method begins with integrally forming a CMOS driver 1002 in and/or on a substrate 1004 (step 902). Generally, the driver 1002 includes multiple layers of vias, metal interconnect layers, and CMOS transistors or devices, formed in the substrate or in dielectric layers 1006 overlying the substrate using standard semiconductor fabrication techniques.

Next, a common electrode 1008 is formed in or a surface 1010 overlying the substrate 1004 and electrically coupled to the driver 1002 through a via 1012 (step 904).

A first germanium sacrificial layer 1014 is then formed on the surface 1010 overlying the substrate 1004 and patterned (step 906). Patterning the first germanium sacrificial layer 1014 generally includes forming a number of holes for posts 1016 that will subsequently be formed to support an actuator and an electrically insulated contact 1020 that will electrically couple the actuator to the driver 1002.

A first SiGe layer is then formed on the first sacrificial layer 1014 and patterned to form a number of electrostatically displaceable actuators 1022, each actuator electrically coupled to the driver (step 908). Generally, the first SiGe layer is a conformal layer of silicon-germanium that fills the post holes to form the posts 1016, and is patterned to form an electrostatically displaceable actuator 1022 including a central plate (CP 1022a) and a number of flexures 1022b through which the CP is flexibly coupled to the posts. The actuator 1022 is electrically coupled to the driver 1002 through the electrically insulated contact 1020. As noted above, the first SiGe layer is formed by CVD or PECVD deposition at a low temperature of less than about 500 C to yield an amorphous first SiGe layer, and is implanted with impurities at a concentration selected to change stress in the first SiGe layer from a compressive stress to a tensile stress to form a tensile, amorphous first SiGe layer. Generally, the first SiGe layer is annealed at a low temperature of less than about 500 C following the ion implant.

Next, a second germanium sacrificial layer 1024 is formed on the patterned first SiGe layer and patterned (step 910). Patterning the second germanium sacrificial layer 1024 generally includes forming a hole for a center post 1026 that will subsequently be formed to support a number of mirrors 1028 above each of the electrostatically displaceable actuator 1022.

A second SiGe layer is then formed on the second sacrificial layer 1024 and patterned to form the mirror 1028 supported by and separated from the surface 1010 overlying the substrate 1004 by each of the number of actuators 1022 (step 912). As with the SiGe layer used to form the actuators 1022, the second SiGe layer is a conformal layer that fills the hole for the center post 1026. The second SiGe layer is formed by CVD or PECVD deposition at a low temperature of less than about 500 C to yield an amorphous second SiGe layer, and is implanted with dopant ions or impurities at a concentration selected to change stress in the second SiGe layer from a compressive stress to a tensile stress to form a tensile, amorphous first SiGe layer. Generally, the second SiGe layer is annealed at a low temperature of less than about 500 C following the ion implant.

A reflective surface 1030 is formed on the mirrors 1028 to yield the MEMS structure shown in FIG. 10, and the first germanium sacrificial layer 1014 and the second germanium sacrificial layer 1024 are etched or removed to release the mirrors 1028 and actuators 1022, resulting in a 2D modulator as shown in FIGS. 4A-4C (step 914).

Thus, monolithic MEMS-based SLM including 2D MEMS-based modulators formed on a surface of a substrate overlying a driver integrally formed in the substrate below the modulators, have been disclosed. Embodiments of the present invention have been described above with the aid of functional and schematic block diagrams illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

It is to be understood that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The breadth and scope of the present invention should not be limited by any of the above-described exemplary embodiments, but should be defined only in accordance with the following claims and their equivalents.

What is claimed is:

1. A microelectromechanical systems (MEMS) based spatial light modulator (SLM) for modulating light incident thereon, the SLM comprising:
a substrate including a common electrode;
a number of two dimensional (2D) modulators, each including:
an electrostatically displaceable actuator suspended above an upper surface on the substrate, the actuator including an actuator electrode and comprising a layer of tensile, amorphous silicon-germanium (SiGe layer); and
a mirror supported by and separated from the upper surface on the substrate by the actuator, the mirror including a first light reflective surface facing away from the actuator,
wherein the actuator in each of the number of 2D modulators is operable to displace the mirror in response to voltages applied to the common electrode and actuator electrode.

2. The SLM of claim 1, further comprising a driver monolithically integrated in the substrate below the upper surface, the driver electrically coupled to the common electrode and the actuator electrode and operable to apply voltages thereto.

3. The SLM of claim 2, wherein the driver comprises a plurality of layers of vias, metal interconnect layers, and complementary metal-oxide-semiconductor (CMOS) transistors.

4. The SLM of claim 2, wherein the SiGe layer in the actuator in each of the number of 2D modulators is an implanted SiGe layer implanted with a concentration of impurities selected to change stress in the SiGe layer from a compressive stress to a tensile stress.

5. The SLM of claim 4, wherein the impurities implanted include dopants, and the implanted SiGe layer is conductive and functions as the actuator electrode.

6. The SLM of claim 2, wherein the actuator comprises a central plate and a plurality of flexures extending from the central plate to a plurality of posts extending from the upper surface on the substrate and supporting the actuator above the upper surface, and wherein the mirror is supported by and separated from the actuator by a central post extending from the central plate.

7. The SLM of claim 6, further comprising a static faceplate disposed above the upper surface on the substrate, the static faceplate including a second light reflective surface facing away from the upper surface and adjacent to the first light reflective surface, wherein an area of reflectivity of the first light reflective surface and second light reflective surface are substantially equal, and the SLM is operable to modulate an amplitude of light incident thereon by displacing the first light reflective surface so that light reflected from the first light reflective surface interferes with light reflected from the second light reflective surface.

8. The SLM of claim 7, wherein the central post and plurality of posts comprise SiGe, and the faceplate comprises a tensile, amorphous SiGe layer.

9. The SLM of claim 7, wherein the driver is operable to electrostatically displace the actuators in each of the 2D modulators in an analog range of distances so that a gray scale is achieved in the amplitude of the light reflected by the SLM.

10. The SLM of claim 6, wherein the number of 2D modulators are operable to form a plurality of pixels, each pixel including one or more of the number of 2D modulators, and further comprising an imaging system including a Fourier transform filter operable to resolve light reflected from each pixel, wherein the plurality of pixels are operable to independently modulate phase aid magnitude of light reflected therefrom.

11. The SLM according to claim 10, wherein peripheral edges of the mirrors of each of the number of 2D modulators abuts peripheral edges of mirrors in adjoining number of 2D modulators, such that substantially none of the light incident on the SLM passes between the mirrors to impinge on the actuators, flexures, posts or the upper surface.

12. A phase modulator comprising:
microelectromechanical systems (MEMS) based spatial light modulator (SLM), including:
a substrate including a common electrode;
a plurality of pixels, each pixel including:
a number of electrostatically displaceable actuators suspended above an upper surface on the substrate, each actuator including a layer of tensile, amorphous silicon-germanium (SiGe layer) that serves as a structural layer of the actuator and as an actuator electrode; and
a number of light reflective surfaces supported by and separated from the upper surface on the substrate by each of the number of actuators;
an imaging system to resolve light reflected from the number of light reflective surfaces in each pixel; and
driver including a plurality of drive channels monolithically integrated in the substrate below the upper surface, the driver electrically coupled to the common electrode and to each actuator electrode, the driver operable to control the plurality of pixels to independently modulate phase and amplitude of light reflected therefrom.

13. The phase modulator of claim 12, wherein the SiGe layer in each of the actuator in is a doped SiGe layer implanted with a concentration of impurities selected to change stress in the SiGe layer from a compressive stress to a tensile stress.

14. The phase modulator of claim 12, wherein the driver comprises a plurality of layers of vias, metal interconnect layers, and complementary metal-oxide-semiconductor (CMOS) transistors.

15. The phase modulator of claim 12, wherein each of the actuators comprise a central plate and a plurality of flexures extending from the central plate to a plurality of posts extending from the upper surface on the substrate and supporting the actuator above the upper surface, and wherein the number of light reflective surfaces are on mirrors supported by and separated from each actuator by a central post extending from the central plate.

16. The phase modulator of claim 15, wherein peripheral edges of the mirror supported by each of the actuators abuts peripheral edges of mirrors supported by adjoining actuators, such that substantially none of a light incident on the SLM passes between the mirrors to impinge on the actuators, flexures, posts or the upper surface.

17. The phase modulator of claim 15, wherein each pixel includes a plurality of electrostatically displaceable actuators supporting light reflective surfaces, and wherein the imaging system includes a Fourier transform filter operable to resolve light reflected from each pixel but not light reflected from the light reflective surface supported above each actuator in each pixel.

18. An intermediate microelectromechanical systems (MEMS) structure comprising:
a substrate having integrally formed therein a driver including a plurality of layers of vias, metal interconnect layers, and complementary metal-oxide-semiconductor (CMOS) transistors;
a common electrode in a surface overlying the substrate and electrically coupled to the driver;
a first germanium sacrificial layer formed on the surface overlying the substrate; and
a first conformal silicon-germanium layer (first SiGe layer) deposited on the sacrificial layer and patterned to form a number of electrostatically displaceable actuators, each actuator electrically coupled to the driver,
wherein the first SiGe layer is formed by deposition at less than about 500 C to yield an amorphous first SiGe layer, and is implanted with impurities at a concentration selected to change stress in the first SiGe layer from a compressive stress to a tensile stress to form a tensile, amorphous first SiGe layer.

19. The intermediate MEMS structure of claim 18, further comprising:
a second germanium sacrificial layer formed on the first SiGe layer; and
a second silicon-germanium layer (second SiGe layer) deposited on the second sacrificial layer and patterned to form a number of a number of mirrors supported by and separated from the surface overlying the substrate by each of the number of actuators,
wherein the second SiGe layer is formed by deposition at less than about 500 C to yield an amorphous second SiGe layer, and is implanted with impurities at a concentration selected to change stress in the second SiGe layer from a compressive stress to a tensile stress to form a tensile, amorphous first SiGe layer.
